(19) United States
(12) Patent Application Publication
(10) Pub. No.: US 2026/0082737 A1
(43) Pub. Date: Mar. 19, 2026

(54) VERTICAL FLIP-CHIP LIGHT EMITTING ELEMENT AND MANUFACTURING METHOD FOR VERTICAL FLIP-CHIP LIGHT EMITTING ELEMENT

(71) Applicant: INGENTEC CORPORATION, Miaoli County (TW)

(72) Inventors: Chia-Pin WANG, Miaoli County (TW); Hsiao-Lu CHEN, Miaoli County (TW); Ai-Sen LIU, Miaoli County (TW); Hsiang-An FENG, Miaoli County (TW)

(21) Appl. No.: 19/023,191

(22) Filed: Jan. 15, 2025

(30) Foreign Application Priority Data
Sep. 13, 2024 (TW) 113134993

(51) Int. Cl. H10H 20/831; H10H 20/01

(52) U.S. Cl. CPC H10H 20/8314; H10H 20/032

(57) ABSTRACT

A vertical flip-chip light emitting element includes a die set including two dice and a first-type semiconductor connecting portion, two first pads, two second pads and an electric connecting layer. The first-type semiconductor connecting portion is connected between the first-type semiconductor layers of the dice. A first one of the first pads is disposed under a first one of the dice, and a second one of the first pads corresponds to a second one of the dice while does not contact the second one of the dice directly. A first one of the second pads is disposed above the first one of the dice, and a second one of the second pads is disposed above the second one of the dice. The electric connecting layer is electrically connected to the second pads and the second one of the first pads.

### RELATED APPLICATIONS

This application claims priority to Taiwan Application Serial Number 113134993, filed Sep. 13, 2024, which is herein incorporated by reference.

### BACKGROUND

### Technical Field

The present disclosure relates to a light emitting element and a manufacturing method for light emitting elements. More particularly, the present disclosure relates to a vertical flip-chip light emitting element and a manufacturing method for vertical flip-chip light emitting elements.

### Description of Related Art

The development of the technique makes the sizes of the light emitting diodes (LEDs) become smaller, which is favorable for the LEDs to be applied to lots of products. For example, the mini LEDs or the micro LEDs are applied to displays. In addition, Chips On Board (COB) LEDs become popular owing to that the dice are directly attached to the circuit board or the substrate.

Flip-chip LEDs are preferred for COB LEDs because they can be directly attached to the substrate without wires. However, without the protection of package layers, the Flip-chip LEDs are not easily repaired when being damaged, and improvement is required.

### SUMMARY

According to one aspect, the present disclosure provides a vertical flip-chip light emitting element including a die set, two first pads, two second pads and an electric connecting layer. The die set includes two dice and a first-type semiconductor connecting portion. Each of the two dice includes a first-type semiconductor layer, an active layer and a second-type semiconductor layer. The first-type semiconductor connecting portion is connected between the first-type semiconductor layers of the two dice. A first one of the two first pads is disposed under a first one of the two dice or under the first-type semiconductor connecting portion, and a second one of the two first pads corresponds to a second one of the two dice while does not contact the second one of the two dice directly. A first one of the two second pads is disposed above the first one of the two dice, and a second one of the two second pads is disposed above the second one of the two dice. The electric connecting layer is electrically connected to the two second pads and the second one of the two first pads. A first branch of a current flows via the first one of the two first pads, the first one of the two dice, the first one of the two second pads, the electric connecting layer and the second one of the two first pads. A second branch of the current flows via the first one of the two first pads, the first-type semiconductor connecting portion, the second one of the two dice, the second one of the two second pads, the electric connecting layer and the second one of the two first pads.

According to another aspect, the present disclosure provides a manufacturing method for vertical flip-chip light emitting elements including an epitaxy structure forming step, a first pad forming step, an original substrate removing step, an etching step, a second pad forming step, and an electric connecting layer forming step. In the epitaxy structure forming step, an epitaxy structure is formed on an original substrate. In the first pad forming step, a plurality of first pad sets are formed on the epitaxy structure, each of the first pad sets including two first pads and an insulating layer, for each of the first pad sets, a first one of the two first pads is connected to a proximal side of the insulating layer, a second one of the two first pads covers a distal side of the insulating layer, and the first one of the two first pads and the second one of the two first pads does not contact to each other directly. In the original substrate removing step, the first pads are attached to a temporary substrate, and the original substrate is removed. In the etching step, the epitaxy structure is etched to form a plurality of die sets, each of the die sets includes two dice and a first-type semiconductor connecting portion, for each of the die sets, each of the two dice includes a first-type semiconductor layer, an active layer and a second-type semiconductor layer, the first-type semiconductor connecting portion is connected between the first-type semiconductor layers of the two dice, each of the die sets corresponds to each of the first pad sets, for each of the die sets and the first pad set corresponding thereto, the first one of the two first pads is directly attached below a first one of the two dice, and the insulating layer is directly attached below a second one of the two dice. In the second pad forming step, a plurality of second pad sets are formed to respectively correspond to the die sets, each of the second pad sets includes two second pads, for each of the die sets and the second pad sets corresponding thereto, a first one of the two second pads is disposed above the first one of the two dice, and a second one of the two second pads is disposed above the second one of the two dice. In the electric connecting layer forming step, a plurality of electric connecting layers are formed to respectively correspond to the die sets. For each of the electric connecting layers and the first pad set and the second pad set corresponding thereto, the electric connecting layer is electrically connected to the two second pads and the second one of the two first pads.

### BRIEF DESCRIPTION OF THE DRAWINGS

The present disclosure can be more fully understood by reading the following detailed description of the embodiment, with reference made to the accompanying drawings as follows:

FIG. 1 is a side view of a vertical flip-chip light emitting element according to one embodiment of the present disclosure.

FIG. 2 is a flow chart of a manufacturing method for vertical flip-chip light emitting elements according to another embodiment of the present disclosure.

FIG. 3 is a first manufacture side view of the manufacturing method for the vertical flip-chip light emitting elements of FIG. 2.

FIG. 4 is a second manufacture side view of the manufacturing method for the vertical flip-chip light emitting elements of FIG. 2.

FIG. 5 is a third manufacture side view of the manufacturing method for the vertical flip-chip light emitting elements of FIG. 2.

FIG. 6 is a top view of the manufacturing method for the vertical flip-chip light emitting elements of FIG. 2.

FIG. 7 is a bottom view of the manufacturing method for the vertical flip-chip light emitting elements of FIG. 2.

### DETAILED DESCRIPTION

The embodiments of the present disclosure will be illustrated with drawings hereinafter. In order to clearly describe the content, many practical details will be mentioned with the description hereinafter. However, it will be understood by the reader that the practical details will not limit the present disclosure. In other words, in some embodiment of the present disclosure, the practical details are not necessary. Additionally, in order to simplify the drawings, some conventional structures and elements will be illustrated in the drawings in a simple way; the repeated elements may be labeled by the same or similar reference numerals.

In addition, the terms first, second, third, etc., are used herein to describe various elements or components, these elements or components should not be limited by these terms. Consequently, a first element or component discussed below could be termed a second element or component. Moreover, the combinations of the elements, the components, the mechanisms and the modules are not well-known, ordinary or conventional combinations, and whether the combinations can be easily completed by the one skilled in the art cannot be judged based on whether the elements, the components, the mechanisms or the module themselves are well-known, ordinary or conventional.

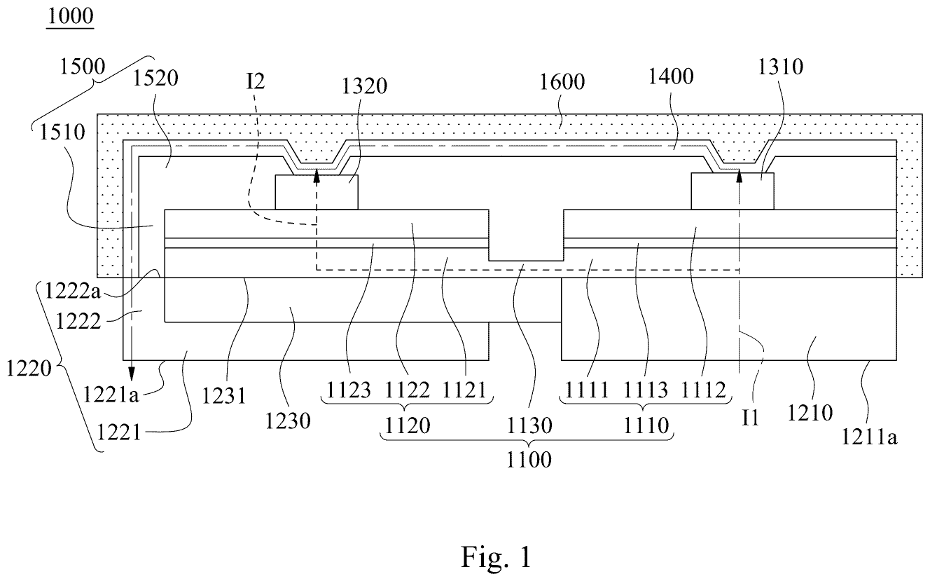

FIG. 1 is a side view of a vertical flip-chip light emitting element 1000 according to one embodiment of the present disclosure. The vertical flip-chip light emitting element 1000 includes a die set 1100, two first pads 1210, 1220, two second pads 1310, 1320 and an electric connecting layer 1400.

The die set 1100 includes two dice 1110, 1120 and a first-type semiconductor connecting portion 1130. Each of the two dice 1110, 1120 includes a first-type semiconductor layer 1111, 1121, an active layer 1113, 1123 and a second-type semiconductor layer 1112, 1122. The first-type semiconductor connecting portion 1130 is connected between the first-type semiconductor layers 1111, 1121 of the two dice 1110, 1120.

A first one of the two first pads 1210, 1220, i.e., the first pad 1210 being referred hereinafter, is disposed under a first one of the two dice 1110, 1120, i.e., the die 1110 being referred hereinafter, or under the first-type semiconductor connecting portion 1130, and a second one of the two first pads 1210, 1220, i.e., the first pad 1210 being referred hereinafter, correspond to a second one of the two dice 1110, 1120 i.e., the die 1120 being referred hereinafter, while does not contact the die 1120 directly. A first one of the two second pads 1310, 1320, i.e., the second pad 1310 being referred hereinafter, is disposed above the die 1110, and a second one of the two second pads 1310, 1320, i.e., the second pad 1320 being referred hereinafter, is disposed above the die 1120. The electric connecting layer 1400 is electrically connected to the two second pads 1310, 1320 and the first pads 1220.

A first branch I1 of a current flows via the first pad 1210, the die 1110, the second pad 1310, the electric connecting layer 1400 and the first pad 1220. A second branch I2 of the current flows via the first pad 1210, the first-type semiconductor connecting portion 1130, the die 1120, the second pad 1320, the electric connecting layer 1400 and the first pad 1220.

Therefore, with the configuration that both of the two dice 1110, 1120 have a vertical light emitting diode structure, are electrically connected to each other via the first-type semiconductor connecting portion 1130 and share the two first pads 1210, 1220, the goal of easy bonding as the flip-chip LED may be achieved. In addition, as one of the dice 1110, 1120 is damaged, the current may flow via another normal one of the dice 1110, 1120 to emit light, thereby being capable of self-compensation, and no extra repair is required.

For each of the dice 1110, 1120, the first-type semiconductor layer 1111, 1121 may be N-type nitride semiconductor stack layers made by adding N-type dopants to GaN, AlGaN, AlInGaN or InGaN. The active layer 1113, 1123 can be made of quantum wells, such as multiple quantum wells. The second-type semiconductor layer 1112, 1122 may be P-type nitride semiconductor stack layers made by adding P-type dopants to GaN, AlGaN, AlInGaN or InGaN. The present disclosure is not limited thereto. The material of the first-type semiconductor connecting portion 1130 is the same as the first-type semiconductor layer 1111, both of them may be formed integrally, and partial material may be removed by etching, but the present disclosure is not limited thereto.

The first pads 1210, 1220 may be a conductive metal. The vertical flip-chip light emitting element 1000 may further include an insulating layer 1230 directly disposed under the die 1120, and the first pad 1220 is at least partially located below the insulating layer 1230. Moreover, the first pad 1220 may include a metal upper surface 1222a being not covered by the insulating layer 1230. The metal upper surface 1222a may be aligned with an insulating upper surface 1231 of the insulating layer 1230, and a metal lower surface 1211a of the first pad 1210 is aligned with a metal lower surface 1221a of the first pad 1220.

Precisely, the insulating layer 1230 is located below the first-type semiconductor layer 1121 of the die 1120 and a proximal side of the insulating layer 1230 contacts a side edge of the first pad 1210. The first pad 1220 may include a bonding segment 1221 and a protruded segment 1222. The bonding segment 1221 is located below the insulating layer 1230 and does not contact to the first pad 1210. The protruded segment 1222 is connected to the bonding segment 1221 and is located at a distal side of the insulating layer 1230. The metal upper surface 1222a indicates the surface of the protruded segment 1222 near the die 1120. The metal upper surface 1222a may be as tall as the insulating upper surface 1231 and is aligned with the insulating upper surface 1231. The metal lower surface 1211a of the first pad 1210 indicates the surface being far away from the die 1110, and the metal lower surface 1221a of the first pad 1220 indicates the surface being far away from the die 1120. The metal lower surface 1211a is as low as the metal lower surface 1221a, and the metal lower surface 1211a is aligned with metal lower surface 1221a. Therefore, the vertical flip-chip light emitting element 1000 is favorable for being manufactured and bonded in the later.

The second pad 1310 may be disposed above the die 1110, the second pad 1320 may be disposed above the die 1120, and the second pad 1310 and the second pad 1320 are both metal. The vertical flip-chip light emitting element 1000 may further include a first protecting layer 1500 covering the two dice 1110, 1120 and including two apertures (not labeled). The two apertures respectively correspond to the two second pads 1310, 1320, thereby exposing the two second pads 1310, 1320. The electric connecting layer 1400 is located above the first protecting layer 1500 and electrically connected to the two second pads 1310, 1320 respectively protruding from the two apertures. An extension portion 1510 of the first protecting layer 1500 extends toward the metal upper surface 1222a via an outer side wall of the die 1120, and the electric connecting layer 1400 is located outside the extension portion 1510 and extends toward the metal upper surface 1222a.

To be more specific, the first protecting layer 1500 may further include an upper portion 1520 covering the dice 1110, 1120 and the first-type semiconductor connecting portion 1130 to protect the dice 1110, 1120 and the first-type semiconductor connecting portion 1130. The extension portion 1510 may extend downward from the upper portion 1520 to cover the outer side wall of the die 1120. Hence, as the electric connecting layer 1400 extends downward to the metal upper surface 1222a to connect to the first pad 1220, the extension portion 1510 may isolate the electric connecting layer 1400 from the die 1120. In addition, since the electric connecting layer 1400 is electrically connected to the two second pads 1310, 1320, the two apertures may be respectively placed in positions of the upper portion 1520 of the first protecting layer 1500 corresponding to the two second pads 1310, 1320, thereby exposing the second pads 1310, 1320 for electrically connecting to the electric connecting layer 1400.

As shown in FIG. 1, the vertical flip-chip light emitting element 1000 may further include a second protecting layer 1600 covering the electric connecting layer 1400 to further protect the outer side wall of the die 1110, i.e., the exposed portion of the right side of FIG. 1, and a portion of the electric connecting layer 1400 located outside the extension portion 1510. Hence, the electric connecting layer 1400 may be protected by the second protecting layer 1600.

In an application, the two first pads 1210, 1220 may be welded on a circuit board, and the vertical flip-chip light emitting element 1000 is powered via the two first pads 1210, 1220. If the two dice 1110, 1120 are both normal, the first branch I1 may flow into the first-type semiconductor layer 1111, the active layer 1113 and the second-type semiconductor layer 1112 of the die 1110, and the second pad 1310 via the first pad 1210, and then flows into the first pad 1220 via the electric connecting layer 1400, and the second branch I2 may flow into the first-type semiconductor layer 1111 of the die 1110, the first-type semiconductor connecting portion 1130, the first-type semiconductor layer 1121, the active layer 1123 and the second-type semiconductor layer 1122 of the die 1120, and the second pad 1320 via the first pad 1210, and then flows into the first pad 1220 via the electric connecting layer 1400. Therefore, the two dice 1110, 1120 may emit light normally. However, if the die 1110 is damaged, the current may totally follow the route of the second branch I2, and the die 1120 emits light. On the contrary, if the die 1120 is damaged, the current may totally follow the route of the first branch I1, and the die 1110 emits light. As a result, whether the die 1110 is damaged or the die 1120 is damaged, the vertical flip-chip light emitting element 1000 can still emit light, thereby having a self-compensating function, and no extra repair is required. It is noted that, in order to clearly show the structure of each layers, the thickness is not illustrated in a real dimension in FIG. 1. The thickness of the electric connecting layer 1400 may for example be smaller than 100 nm, the thickness of the first protecting layer 1500 may for example be in a range from 40 μm to 50 μm, the thickness of the second protecting layer 1600 may for example be in a range from 50 μm to 60 μm, and the present disclosure is not limited to the drawings.

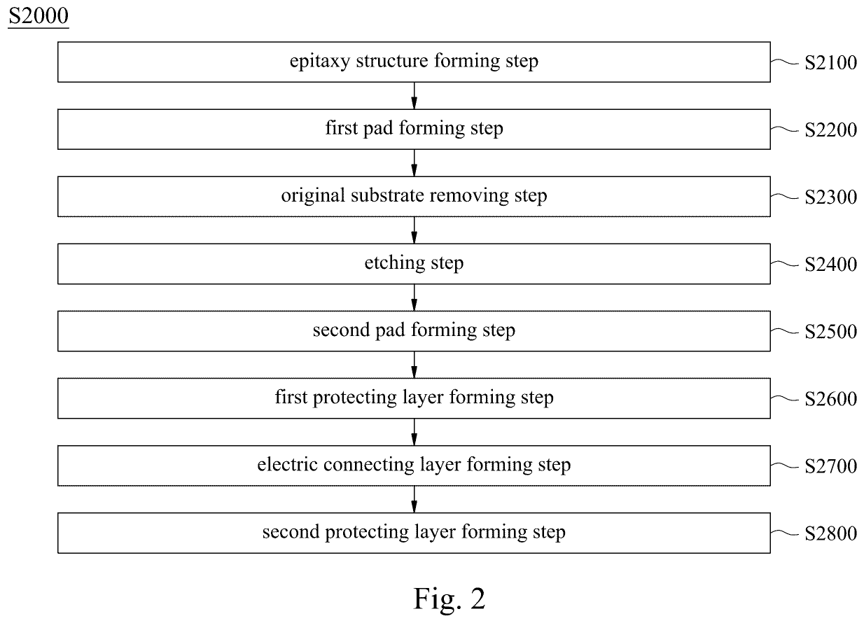

FIG. 2 is a flow chart of a manufacturing method S2000 for vertical flip-chip light emitting elements 2000 according to another embodiment of the present disclosure. The manufacturing method S2000 includes an epitaxy structure forming step S2100, a first pad forming step S2200, an original substrate removing step S2300, an etching step S2400, a second pad forming step S2500, and an electric connecting layer forming step S2700.

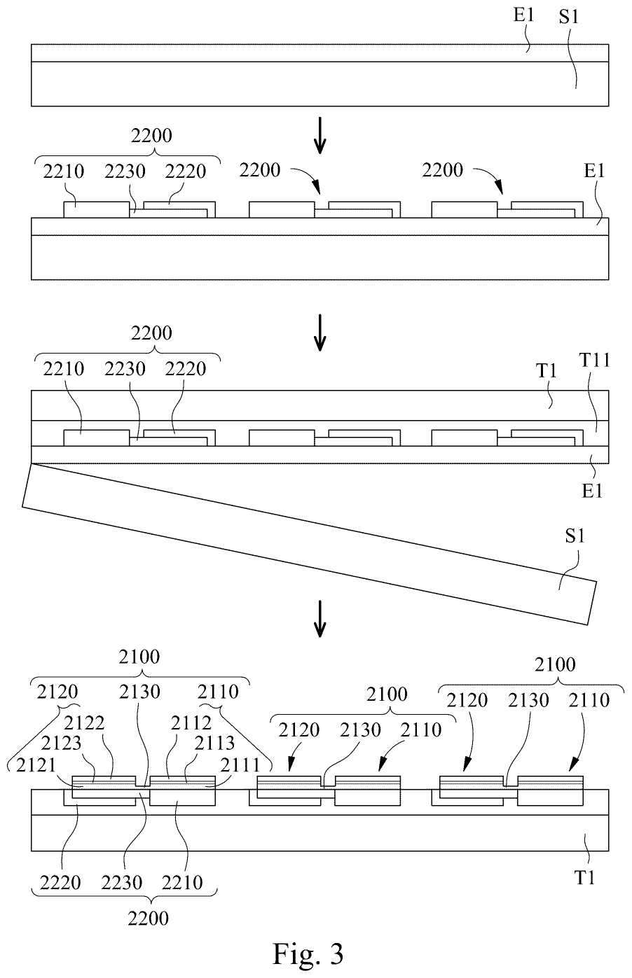

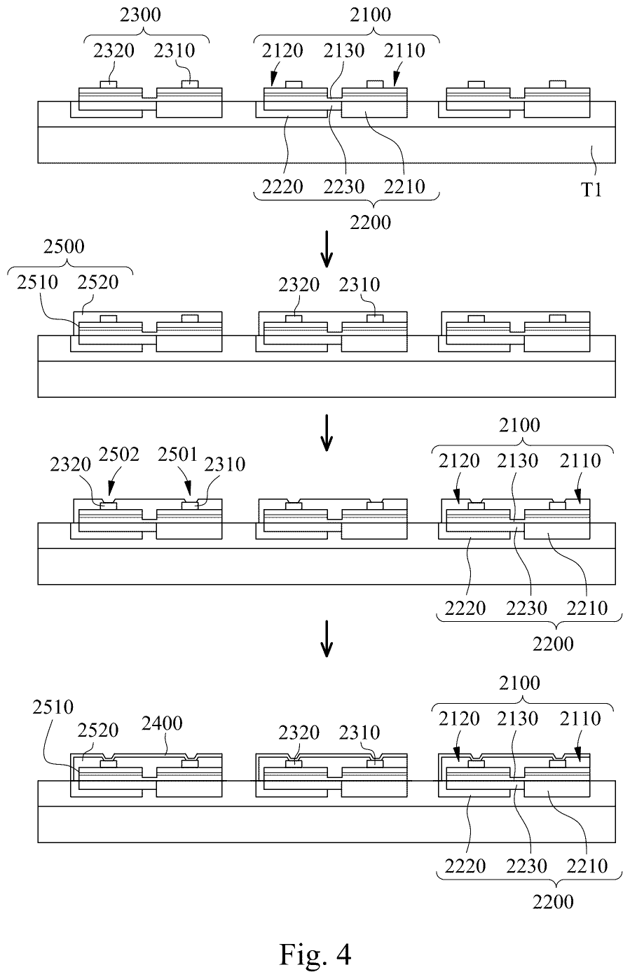

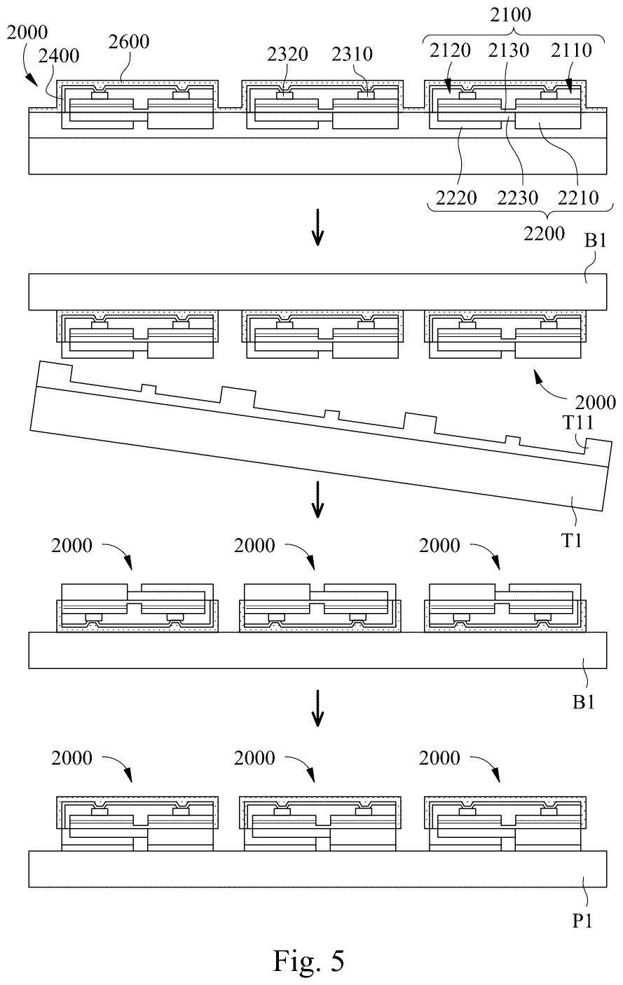

FIG. 3 is a first manufacture side view of the manufacturing method S2000 for the vertical flip-chip light emitting elements 2000 of FIG. 2. FIG. 4 is a second manufacture side view of the manufacturing method S2000 for the vertical flip-chip light emitting elements 2000 of FIG. 2. FIG. 5 is a third manufacture side view of the manufacturing method S2000 for the vertical flip-chip light emitting elements 2000 of FIG. 2. The details of the manufacturing method S2000 will be described with the references of FIGS. 2 to 5.

In the epitaxy structure forming step S2100, an epitaxy structure E1 is formed on an original substrate S1.

In the first pad forming step S2200, a plurality of first pad sets 2200 are formed on the epitaxy structure E1, each of the first pad sets 2200 includes two first pads 2210, 2220 and an insulating layer 2230. For each of the first pad sets 2200, a first one of the two first pads 2210, 2220, i.e., the first pad 2210 being referred hereinafter, is connected to a proximal side of the insulating layer 2230, a second one of the two first pads 2210, 2220, i.e., the first pad 2220 being referred hereinafter, covers a distal side of the insulating layer 2230, and the first pad 2210 and the first pad 2220 does not contact to each other directly.

In the original substrate removing step S2300, the first pads 2210, 2220 are attached to a temporary substrate T1, and the original substrate S1 is removed.

In the etching step S2400, the epitaxy structure E1 is etched to form a plurality of die sets 2100, and each of the die sets 2100 includes two dice 2110, 2120 and a first-type semiconductor connecting portion 2130. For each of the die sets 210, each of the two dice 2110, 2120 includes a first-type semiconductor layer 2111, 2121, an active layer 2113, 2123 and a second-type semiconductor layer 2112, 2122, and the first-type semiconductor connecting portion 2130 is connected between the first-type semiconductor layers 2111, 2121 of the two dice 2110, 2120. Each of the die sets 2100 corresponds to each of the first pad sets 2200. For each of the die sets 2100 and the first pad set 2200 corresponding thereto, the first pad 2210 is directly attached below a first one of the two dice 2110, 2120, i.e., the die 2110 being referred hereinafter, and the insulating layer 2230 is directly attached below a second one of the two dice 2110, 2120, i.e., the die 2120 being referred hereinafter.

In the second pad forming step S2500, a plurality of second pad sets 2300 are formed to respectively correspond to the die sets 2100, and each of the second pad sets 2300 includes two second pads 2310, 2320. For each of the die sets 2100 and the second pad sets 2300 corresponding thereto, a first one of the two second pads 2310, 2320, i.e., the second pad 2310 being referred hereinafter, is disposed above the die 2110, and a second one of the two second pads 2310, 2320, i.e., the second pad 2320 being referred hereinafter, is disposed above the die 2120.

In the electric connecting layer forming step S2700, a plurality of electric connecting layers 2400 are formed to respectively correspond to the die sets 2100. For each of the electric connecting layer 2400 and the first pad set 2200 and the second pad set 2300 corresponding thereto, the electric connecting layer 2400 is electrically connected to the two second pads 2310, 2320 and the first pad 2220.

The manufacturing method S2000 may further include a first protecting layer forming step S2600. A plurality of first protecting layers 2500 are formed to respectively correspond to the die sets 2100. For each of the die sets 2100 and the second pad set 2300, the electric connecting layer 2400 and the first protecting layer 2500 corresponding thereto, the first protecting layer 2500 covers the die set 2100 and includes two apertures 2501, 2502, the two apertures 2501, 2502 respectively correspond to the two second pads 2310, 2320 to expose the two second pads 2310, 2320, and the electric connecting layer 2400 is located above the first protecting layer 2500 to electrically connected to the two second pads 2310, 2320 protruding from the two apertures 2501, 2502.

The manufacturing method S1000 may further include a second layer forming step S2800. A plurality of second protecting layers 2600 are formed to respectively correspond to the die sets 2100, and each of the second protecting layer 2600 covers each of the electric connecting layer 2400.

As shown in FIGS. 2 and 3, in the epitaxy structure forming step S2100, the epitaxy structure E1 is formed by conventional epitaxy growing method. The second-type semiconductor material, the active layer material and the first-type semiconductor material are formed in sequence form a lower side to an upper side on the original substrate S1. In the first pad forming step S2200, the first pad sets 2200 are formed on one side of the epitaxy structure E1. Moreover, in order to form the second pad sets 2300 on the other side of the epitaxy structure E1, the substrate S1 may be removed by attaching the epitaxy structure E1 to the temporary substrate T1 for the later process. It is noted that, the temporary substrate T1 may include a glue T11 attached to the first pad sets 2200, and the glue T11 can be deformed by being forced. After attaching the epitaxy structure E1 to the temporary substrate T1, the epitaxy structure E1 may face upward for executing the etching step S2400. In the etching step S2400, unnecessary portions may be removed, and adjacent two of the dice 2110, 2120 may be connected to form one of the die sets 2100. At this time, for the die 2110 and the die 2120, only the first-type semiconductor layer 2111 and the first-type semiconductor layer 2121 are connected via the first-type semiconductor connecting portion 2130, the second-type semiconductor layer 2112 and second-type semiconductor layer 2122 are not directly connected, and the active layer 2113 and the active layer 2123 are also not directly connected.

As shown in FIGS. 2 and 4, the two second pads 2310, 2320 are formed in the second pad forming step S2500. After which, the first protecting layer forming step S2600 is executed. For each of the die sets 2100 and the first pad set 2200, the second pad set 2300, the electric connecting layer 2400 and the first protecting layer 2500 corresponding thereto, an extension portion 2510 of the first protecting layer 2500 extends toward a metal upper surface of the first pad 2220 via an outer side wall of the die 2120. In other words, an upper portion 2520 covering the two dice 2110, 2120 may be formed, and the extension portion 2510 covering the outside wall of the die 2120 are also formed. After the upper portion 2520 covering the two dice 2110, 2120 is formed, it is etched to form the two apertures 2501, 2502 to respectively expose partial surfaces of the two second pads 2310, 2320. After which, in the electric connecting layer forming step S2700, the electric connecting layer 2400 is located outside the extension portion 2510 of the first protecting layer 2500 so as to extend toward the metal upper surface of first pad 2220, thereby completing the electrical connection between second pad 2310, the second pad 2320 and the first pad 2220.

As shown in FIGS. 2 and 5, in the second protecting layer forming step S2800, the second protecting layer 2600 may be formed to complete forming the vertical flip-chip light emitting elements 2000. The plasma bombards the second protecting layer 2600 to partially remove the second protecting layer 2600 without affecting the glue T11, thereby separating the vertical flip-chip light emitting elements 2000.

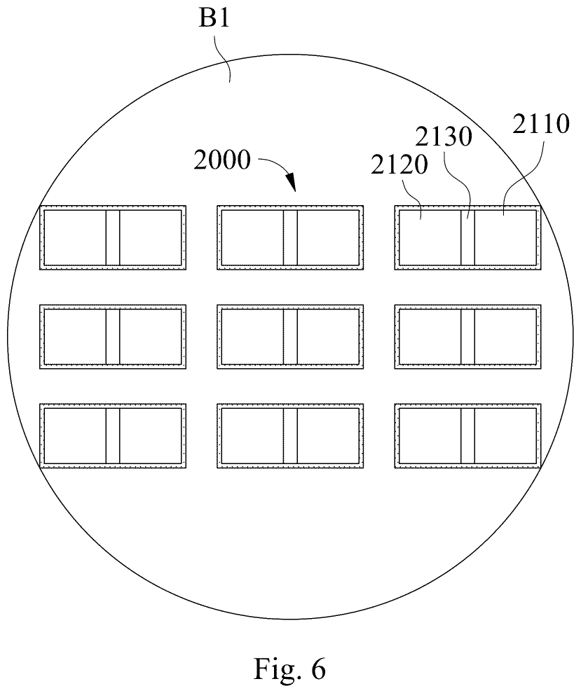

Please refer to FIG. 6 with references of FIG. 5, and FIG. 6 is a top view of the manufacturing method S2000 for the vertical flip-chip light emitting elements 2000 of FIG. 2. As shown in FIGS. 5 and 6, the separated vertical flip-chip light emitting elements 2000 may be placed on a blue film B1, and the temporary substrate T1 is removed for further usage.

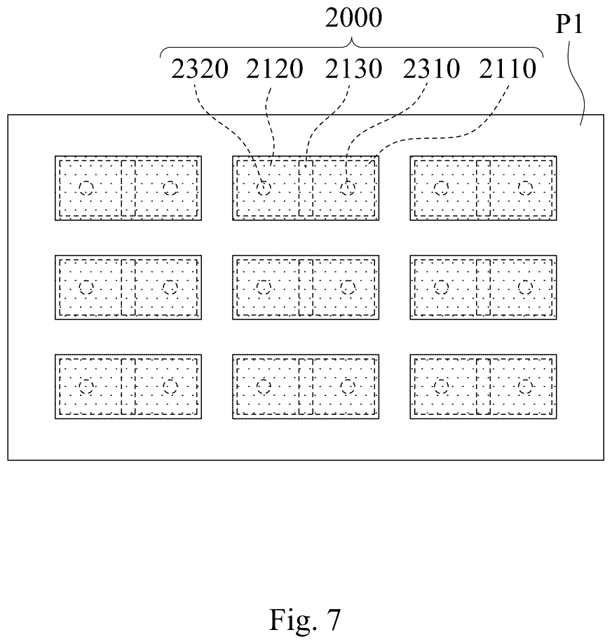

FIG. 7 is a bottom view of the manufacturing method S2000 for the vertical flip-chip light emitting elements 2000 of FIG. 2. The vertical flip-chip light emitting elements 2000 may be welded to a circuit board P1 via pads. With the current provided by the circuit board P1, the vertical flip-chip light emitting elements 2000 may emit light.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A vertical flip-chip light emitting element, comprising:
a die set, comprising:
two dice, each of the two dice comprising a first-type semiconductor layer, an active layer and a second-type semiconductor layer; and
a first-type semiconductor connecting portion connected between the first-type semiconductor layers of the two dice;
two first pads, wherein a first one of the two first pads is disposed under a first one of the two dice or under the first-type semiconductor connecting portion, and a second one of the two first pads corresponds to a second one of the two dice while does not contact the second one of the two dice directly;
two second pads, wherein a first one of the two second pads is disposed above the first one of the two dice, and a second one of the two second pads is disposed above the second one of the two dice; and
an electric connecting layer electrically connected to the two second pads and the second one of the two first pads;
wherein, a first branch of a current flows via the first one of the two first pads, the first one of the two dice, the first one of the two second pads, the electric connecting layer and the second one of the two first pads; a second branch of the current flows via the first one of the two first pads, the first-type semiconductor connecting portion, the second one of the two dice, the second one of the two second pads, the electric connecting layer and the second one of the two first pads.

2. The vertical flip-chip light emitting element of claim 1, further comprising:
an insulating layer directly disposed under the second one of the two dice;
wherein the second one of the two first pads is at least partially located below the insulating layer.

3. The vertical flip-chip light emitting element of claim 2, further comprising:
a first protecting layer covering the two dice and comprising two apertures, wherein the two apertures respectively correspond to the two second pads, thereby exposing the two second pads;
wherein the electric connecting layer is located above the first protecting layer and electrically connected to the two second pads respectively protruding from the two apertures.

4. The vertical flip-chip light emitting element of claim 3, wherein the second one of the two first pads comprises a metal upper surface being not covered by the insulating layer, an extension portion of the first protecting layer extends toward the metal upper surface via an outer side wall of the second one of the two dice, the outer side wall is far from the first one of the two dice, and the electric connecting layer is located outside the extension portion and extends toward the metal upper surface.

5. The vertical flip-chip light emitting element of claim 4, wherein the metal upper surface is aligned with an insulating upper surface of the insulating layer, and a metal lower surface of the first one of the two first pads is aligned with a metal lower surface of the second one of the two first pads.

6. The vertical flip-chip light emitting element of claim 5, further comprising:
a second protecting layer covering the electric connecting layer.

7. A manufacturing method for vertical flip-chip light emitting elements, comprising:
an epitaxy structure forming step, wherein an epitaxy structure is formed on an original substrate;
a first pad forming step, wherein a plurality of first pad sets are formed on the epitaxy structure, each of the first pad sets comprises two first pads and an insulating layer, for each of the first pad sets, a first one of the two first pads is connected to a proximal side of the insulating layer, a second one of the two first pads covers a distal side of the insulating layer, and the first one of the two first pads and the second one of the two first pads does not contact to each other directly;
an original substrate removing step, wherein the first pads are attached to a temporary substrate, and the original substrate is removed;
an etching step, wherein the epitaxy structure is etched to form a plurality of die sets, each of the die sets comprises two dice and a first-type semiconductor connecting portion, for each of the die sets, each of the two dice comprises a first-type semiconductor layer, an active layer and a second-type semiconductor layer, the first-type semiconductor connecting portion is connected between the first-type semiconductor layers of the two dice, each of the die sets corresponds to each of the first pad sets, for each of the die sets and the first pad set corresponding thereto, the first one of the two first pads is directly attached below a first one of the two dice, and the insulating layer is directly attached below a second one of the two dice;
a second pad forming step, wherein a plurality of second pad sets are formed to respectively correspond to the die sets, each of the second pad sets comprises two second pads, for each of the die sets and the second pad sets corresponding thereto, a first one of the two second pads is disposed above the first one of the two dice, and a second one of the two second pads is disposed above the second one of the two dice; and
an electric connecting layer forming step, wherein a plurality of electric connecting layers are formed to respectively correspond to the die sets, wherein for each of the electric connecting layers and the first pad set and the second pad set corresponding thereto, the electric connecting layer is electrically connected to the two second pads and the second one of the two first pads.

8. The manufacturing method of claim 7, further comprising:
a first protecting layer forming step, wherein a plurality of first protecting layers are formed to respectively correspond to the die sets, for each of the die sets and the second pad set, the electric connecting layer and the first protecting layer corresponding thereto, the first protecting layer covers the two dice and comprises two apertures, the two apertures respectively correspond to the two second pads to expose the two second pads, the electric connecting layer is located above the first protecting layer to electrically connected to the two second pads protruding from the two apertures.

9. The manufacturing method of claim 8, further comprising:
a second layer forming step, wherein a plurality of second protecting layers are formed to respectively correspond to the die sets, and each of the second protecting layers covers each of the electric connecting layers.

10. The manufacturing method of claim 9, wherein for each of the die sets and the first pad set, the electric connecting layer and the first protecting layer corresponding thereto, in the first protecting layer forming step, an extension portion of the first protecting layer extends toward a metal upper surface of the second one of the two first pads via an outer side wall of the second one of the two dice, and in the electric connecting layer forming step, the electric connecting layer is located outside the extension portion of the first protecting layer so as to extend toward the metal upper surface of the second one of the two first pads.
